(19) United States
(12) Patent Application Publication
(10) Pub. No.: US 2026/0349354 A1
(43) Pub. Date: Nov. 5, 2026

(54) MULTI-LASER SCAN SYSTEM

(71) Applicant: TOKYO ELECTRON LIMITED, Tokyo (JP)

(72) Inventors: Anton DEVILLIERS, Albany, NY (US); Daniel FULFORD, Albany, NY (US); Mark I. GARDNER, Cedar Creek, TX (US); H. Jim FULFORD, Marianna, FL (US)

(73) Assignee: TOKYO ELECTRON LIMITED, Tokyo (JP)

(21) Appl. No.: 19/196,631

(22) Filed: May 1, 2025

(51) Int. Cl. G03F 7/00; G01B 11/00

(52) U.S. Cl. CPC G03F 7/706847; G01B 11/002; G03F 7/70558; G03F 7/70625; G03F 7/70655; G03F 7/706837; G03F 7/706845; G03F 7/706851

(57) ABSTRACT

A method of wafer processing includes generating a first process beam by a first scanning laser, generating a second process beam by a second scanning laser, directing the first process beam through a first optical hole of an optical bench to a surface of a first wafer placed on a first wafer holder, directing the second process beam through a second optical hole of the optical bench, and laterally scanning the first process beam, the second process beam or both.

### INCORPORATION BY REFERENCE

Aspects of the present disclosure are related to Applicant's co-pending application titled “MULTIPLE LASER BEAM PATHS FOR WAFER PROCESSING” with Attorney Docket No. 555851US, which is incorporated herein by reference in its entirety.

### FIELD OF THE INVENTION

This disclosure relates to semiconductor processing methods and semiconductor processing apparatuses.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Particularly, in the realm of wafer processing technology, laser systems play a vital role. The use of lasers facilitates precise and efficient operations, with a myriad of applications in semiconductor manufacturing, the electronics industry and more.

### SUMMARY

The present disclosure relates to an apparatus and a method of wafer processing.

According to aspect (1) of the disclosure, a method of wafer processing is provided. The method includes generating a first process beam by a first scanning laser, generating a second process beam by a second scanning laser, directing the first process beam through a first optical hole of an optical bench to a surface of a first wafer placed on a first wafer holder, directing the second process beam through a second optical hole of the optical bench, and laterally scanning the first process beam, the second process beam or both.

Aspect (2) includes the method of aspect (1), wherein the second process beam is directed through the second optical hole to the surface of the first wafer.

Aspect (3) includes the method of aspect (2), wherein the first process beam and the second process beam are generated simultaneously.

Aspect (4) includes the method of aspect (1), wherein the second process beam is directed through the second optical hole to a surface of a second wafer placed on a second wafer holder.

Aspect (5) includes the method of aspect (4), wherein the first process beam and the second process beam are generated simultaneously to process the first wafer and the second wafer simultaneously.

Aspect (6) includes the method of aspect (4), wherein the first process beam and the second process beam are generated alternately for alternate wafer processing.

Aspect (7) includes the method of aspect (1), further including generating a critical dimension (CD) correction map based on a CD signature map of the first wafer and pre-determined CD requirements, and executing a location-dependent exposure dosing adjustment based on the CD correction map. The CD signature map includes CD distribution of the first wafer as a result of a photoresist exposure process.

Aspect (8) includes the method of aspect (7), wherein the executing includes varying a laser energy of the first process beam on the first wafer to induce location-dependent changes to a photoresist layer formed on the first wafer, when laterally scanning the first process beam.

Aspect (9) includes the method of aspect (8), further including, before the generating the CD correction map, executing the photoresist exposure process to expose the photoresist layer to patterned actinic radiation.

Aspect (10) includes the method of aspect (9), wherein the location-dependent changes are induced to adjust the CD distribution of the first wafer.

Aspect (11) includes the method of aspect (1), further including, before a failure occurs with the first scanning laser, using the first scanning laser while the second scanning laser is idle. After the failure occurs with the first scanning laser, the second scanning laser is used.

Aspect (12) includes the method of aspect (11), further including pre-aligning the second scanning laser on the optical bench before the using the first scanning laser.

Aspect (13) includes the method of aspect (1), further including splitting the first process beam by a first beam splitter and splitting the second process beam by a second beam splitter.

Aspect (14) includes the method of aspect (13), further including monitoring the first process beam by a first monitoring camera and monitoring the second process beam by a second monitoring camera.

Aspect (15) includes the method of aspect (14), wherein the first process beam is split by the first beam splitter so that part of the first process beam is received by the first monitoring camera, and the second process beam is split by the second beam splitter so that part of the second process beam is received by the second monitoring camera.

Aspect (16) includes the method of aspect (1), further including adjusting the first process beam, the second process beam or both, by a beam modulator.

Aspect (17) includes the method of aspect (1), wherein the beam modulator includes diffraction gratings, polarizers or both.

Aspect (18) includes the method of aspect (1), further including detecting an anomaly of the first process beam, the second process beam or both, by a sensing laser and a sensing camera.

Aspect (19) includes the method of aspect (1), wherein the laterally scanning is executed by a beam steering module includes galvanometers.

Aspect (20) includes the method of aspect (4), further including collecting data on the first scanning laser and the first wafer and adjusting the second scanning laser and the second wafer based on the data.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. Changes and modifications may be made within the scope herein without departing from the spirit and scope thereof. It is noted that, in accordance with the standard practice in the industry, various features are not drawn to scale. In fact, the dimensions of the various features may be increased or reduced for clarity of discussion.

FIG. 1 shows a schematic of an apparatus in accordance with some embodiments of the present disclosure.

FIG. 2 shows schematics of an apparatus in accordance with some embodiments of the present disclosure.

FIGS. 3A, 3B, 3C, 3D and 3E respectively show schematics of an apparatus in various operating modes in accordance with some embodiments of the present disclosure.

FIG. 4 shows a schematic of an apparatus in accordance with some embodiments of the present disclosure.

FIG. 5 shows a flow chart of a process for wafer processing, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

A numerical range represented by “to”, “from . . . to . . . ”, “-” and similar terms includes numerical values at both ends, unless specified otherwise.

As mentioned in the Background, laser systems are widely used in the semiconductor industry. A particular area of interest is the use of multiple parallel laser beams for enhancing tool functionality and throughput. The parallel configuration of lasers enables simultaneous or alternate operation, enhancing the efficiency and versatility of the tool. Coupled with other components such as beam splitters, beam modulators, and power suppliers, these laser systems can form an integral part of advanced wafer processing apparatuses.

However, despite the advanced nature of the technology, certain issues persist. One significant challenge lies in the operation and monitoring of multiple scanning lasers. The simultaneous or alternate operation of these lasers often requires intricate control mechanisms and constant monitoring to ensure smooth operation. Additionally, anomalies in the laser beams can cause inconsistencies in the wafer processing, requiring further checks and adjustments. The use of beam splitters and modulators also adds to the complexity of the system, necessitating precise control and calibration.

Another problem area pertains to the orientation of operation. Many existing systems are limited to either horizontal or vertical orientations, restricting their versatility. Additionally, the transfer of learning from one laser and optics system to another can be a complex process, often requiring advanced artificial intelligence mechanisms. Furthermore, the remote control of such systems can pose challenges due to the intricate nature of the operations involved.

Additionally, a critical requirement of advanced semiconductor processing is the uniformity of the smallest feature size, known as the critical dimension (CD), and the uniformity of alignment between different patterning layers in a circuit, referred to as overlay (OL). These uniformities need to be maintained over the entire wafer surface. As the feature sizes of semiconductor circuits continue to shrink, maintaining CD and OL uniformity becomes increasingly challenging. For example, a target CD variation of less than 3% across a 300 mm or 450 mm wafer is desired, which means that the CD must vary by less than 0.2 nm for future technology nodes.

The CD uniformity of patterns on semiconductor substrates can be obtained by using CD mapping tools. These tools generate a two-dimensional (2D) map of CD correction sites that can be modified or enhanced using techniques herein. For example, techniques herein can utilize a scanned laser beam to provide localized varying laser energy to a wafer surface for CD correction. This process achieves the essential secondary adjustment required to obtain a smaller sigma and consistent median of the target CD across the wafer surface.

However, several problems persist in the existing technologies. One major issue is the difficulty in maintaining uniformity as feature size continues to decrease. This is due to the stringent requirement of a small sigma and uniformity of the smallest feature size known as the CD. Moreover, the uniformity of alignment between different patterning layers in a circuit, referred to as OL, over the entire wafer surface also poses a significant challenge. The reduction in feature size as per Moore's Law further exacerbates these issues.

Another problem is the need for a secondary adjustment or tuning of the core process using scanned laser beams. This is necessary to deliver a CD variation of less than 3% across a 300 mm or 450 mm wafer and a CD that varies by less than 0.2 nm for future technology nodes. Such precise adjustments are challenging to achieve consistently.

Furthermore, the current CD mapping tools used to obtain the CD uniformity of patterns on semiconductor substrates have their limitations. While these tools can generate a 2D map of CD correction sites, there is still a need for a technique that can provide localized varying laser energy to a wafer surface for CD correction. This is necessary to achieve the essential secondary adjustment required to obtain a smaller sigma and consistent median of the target CD across the wafer surface.

Existing technologies such as those disclosed in U.S. Pat. Nos. 10,108,096B2, 10,503,083B2 and 10,145,672B2 have attempted to solve the aforementioned problems individually or partially. However, these existing technologies still lack the ability to provide a localized varying laser energy to a wafer surface for CD correction.

Therefore, there is a need to overcome the problems discussed above. An ideal solution would be a system that can address the challenges associated with the operation of multiple scanning lasers, orientation of operation, transfer of learning, and remote control. This system could potentially revolutionize the field of wafer processing, paving the way for more efficient and versatile tools.

To address these challenges, techniques herein provide a system that can efficiently operate and monitor multiple scanning lasers, with the ability to sense and correct anomalies in the laser beams. The system is also capable of operating in both horizontal and vertical orientations, enhancing its versatility. Moreover, the integration of an artificial intelligence learning mechanism can facilitate the transfer of learning between different laser and optics systems. Additionally, the system is capable of being controlled remotely, potentially through a digital twin, to allow for more flexible and convenient operation.

Techniques herein provide a dual scan laser system that enhances wafer throughput by e.g. 2 times from the POR yield hunter system. It incorporates multiple components such as scanning lasers, monitoring cameras, sensing lasers, beam splitters, power suppliers, beam modulators, galvanometers, beam steering mirrors, a motherboard, a motion control module, a beam steering module, and photodetectors. The system also features a dual optics compact module that accommodates a pair of lasers and optics which can alternate use or operate one until failure before switching to the backup. The system's optical alignment can be completed at the factory, reducing installation time. The system also allows for the simultaneous exposure of two or more substrates using one optical module, enhancing compactness and reducing tool downtime. The system also utilizes AI learning from one laser/optics system for another when not in use and connects with all yield hunter tools for process optimization at multiple factory locations.

One objective of the present disclosure is to provide a dual (or multiple) scan laser system designed to increase wafer throughput, for instance enabling a 2 times increase in wafer throughput from the POR yield hunter system. This system includes multiple components including two or more scanning lasers, monitoring cameras, one or more sensing lasers, multiple beam splitters, power suppliers, beam modulators, galvanometers for each of the X and Y axes, an optical hole beam, beam steering mirrors, a motherboard, a motion control module, a beam steering module, and photodetectors. This system aims to provide a significant increase in efficiency and productivity in the wafer production process.

Another objective of the present disclosure is to offer a Yield Hunter multiple laser tool scanning and dual optics compact module. This module covers double optics, including laser optics and control system optics. The laser optics can fail at six months, while the system optics can last for two years. The device module, equipped with a pair of lasers and optics, is configured to alternate the use of laser and optics or operate only one until failure, then switch to the backup laser and optics. This configuration provides a robust and reliable system that ensures continuous operation even in the event of component failure.

Yet another objective of the present disclosure is to reduce the time to install the tool by e.g. completing the optical alignment at the factory prior to tool installation. Techniques herein may utilize one optical module to expose two or more functions either independently or simultaneously as options. This design allows a laser tool such as the Yield Hunter to be more compact since it incorporates two or more laser and optic systems in a reduced fab tool. This compact design not only saves space but also enhances the efficiency of the system.

Still another objective of the present disclosure is to reduce the downtime of the tool since a spare laser that is pre-aligned is built onto the optical bench. The system can also utilize artificial intelligence (AI) learning from one laser and optics system for another laser and optics system while not in use. This AI learning capability allows the system to continuously improve and optimize its performance based on past experiences.

A further objective of the present disclosure is to utilize a digital twin (e.g. a duplicate of the dual laser system) at a remote location for operation and continuous enhancement of the dual laser system. According to aspects of the present disclosure, all yield hunter tools may be connected for process optimization at multiple factory locations. This connectivity allows for centralized control and optimization of the entire production process, leading to improved efficiency and productivity.

Aspects of the present disclosure pertain to semiconductor processing, more specifically to the improvement of critical dimension (CD) uniformity and overlay (OL) uniformity across a wafer surface. This is achieved by using variable energy scanning of laser beams. This is particularly relevant in light of the continual reduction in feature size in semiconductor circuits, a trend commonly referred to as Moore's Law. Techniques herein may be applied to all current and future advanced optical systems, including Extreme Ultraviolet (EUV) lithography.

Techniques herein provide a method and a system that can provide localized varying laser energy to a wafer surface for CD correction and achieve the essential secondary adjustment required to obtain a smaller sigma and consistent median of the target CD across the wafer surface, which will be of great benefits to the industry. Such a solution will not only address the limitations of the existing technologies but also enhance device performance and circuit yield.

According to one aspect of the present disclosure, the dual scan laser system can operate in at least two modes. In the first mode, one scanning laser is used while the other laser is idle as a backup. In this configuration, only one laser beam is visible from the cross section, since the other laser beam is not generated (or located into the plane of the paper) and is idle as a backup laser. In the second mode, both scanning lasers are used. In this configuration, both beams are visible from the cross section. Moreover, the system can accommodate N scanning lasers as options, providing flexibility and scalability.

According to another aspect of the present disclosure, the system includes a substrate CD signature correction controller. This controller can include various components including an external communication interface, a control processor, an operating memory, a storage memory, and an external sensor interface. The system also includes a signal control module that includes a beam position driver for the dual laser system. This comprehensive control system ensures precise and accurate operation of the dual laser system.

According to yet another aspect of the present disclosure, the system is capable of CD optimization with a single optical scanned cone for one substrate or simultaneous CD wafer optimization with dual scanned optical cones for two substrates. This flexibility allows the system to adapt to different production requirements and optimize its performance accordingly.

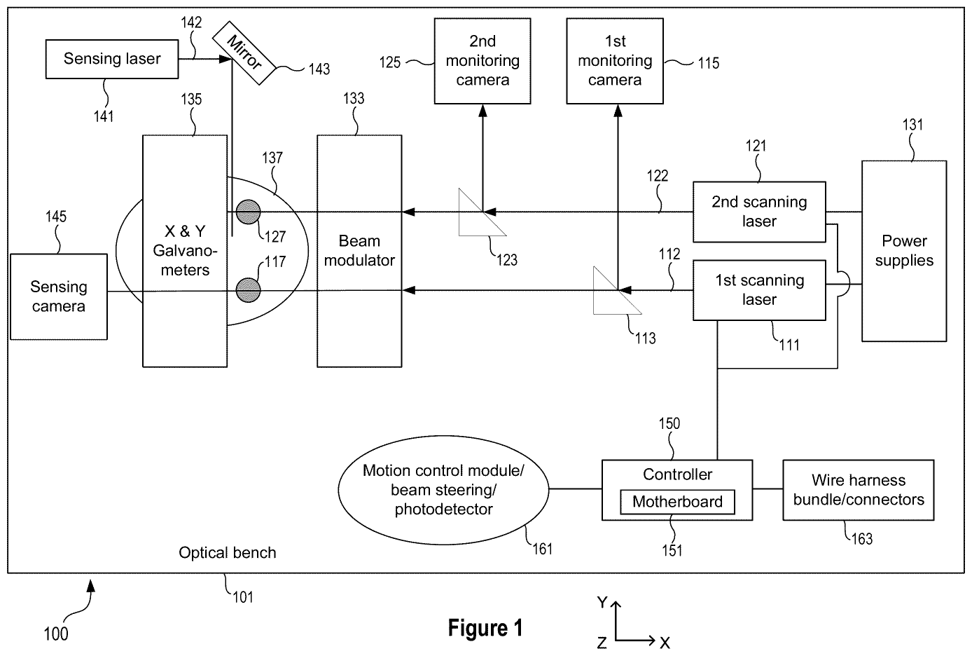

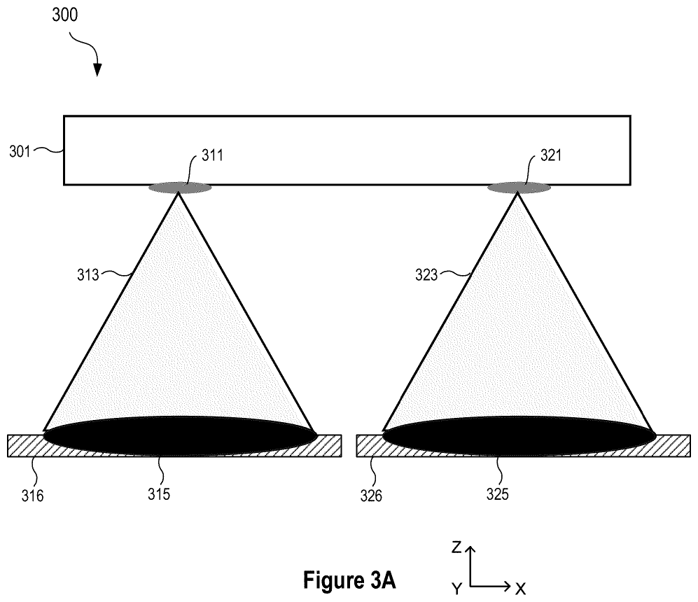

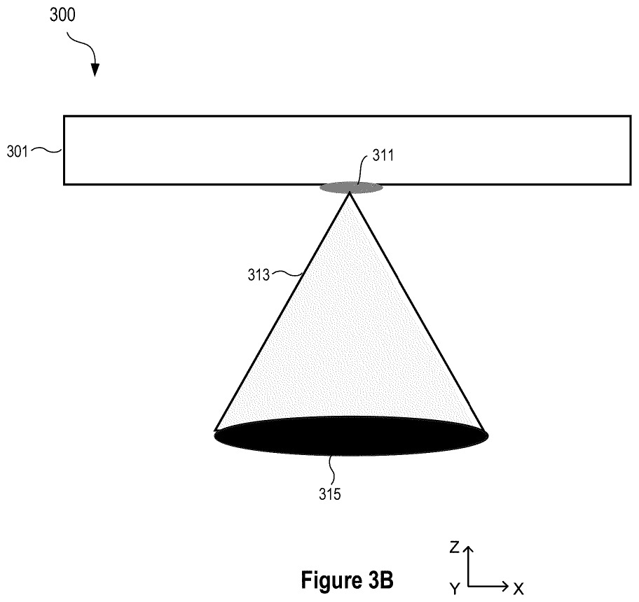

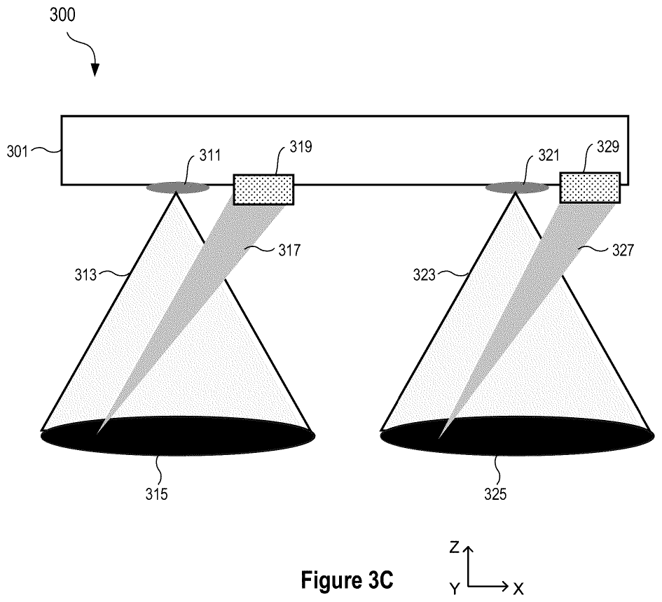

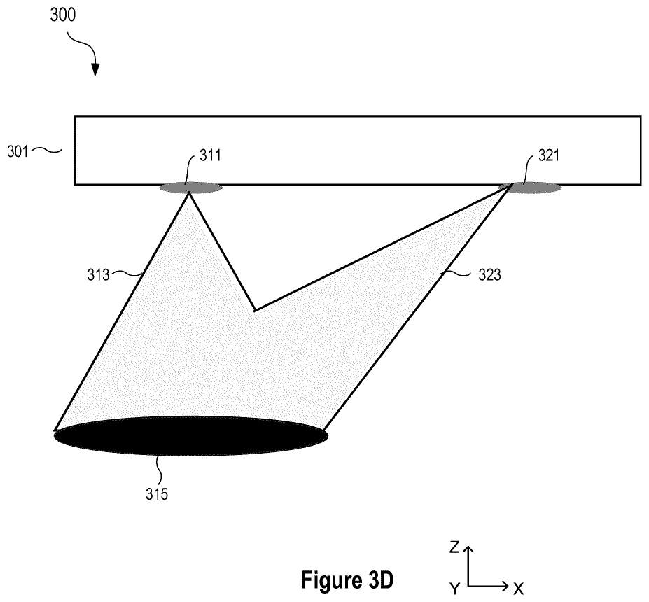

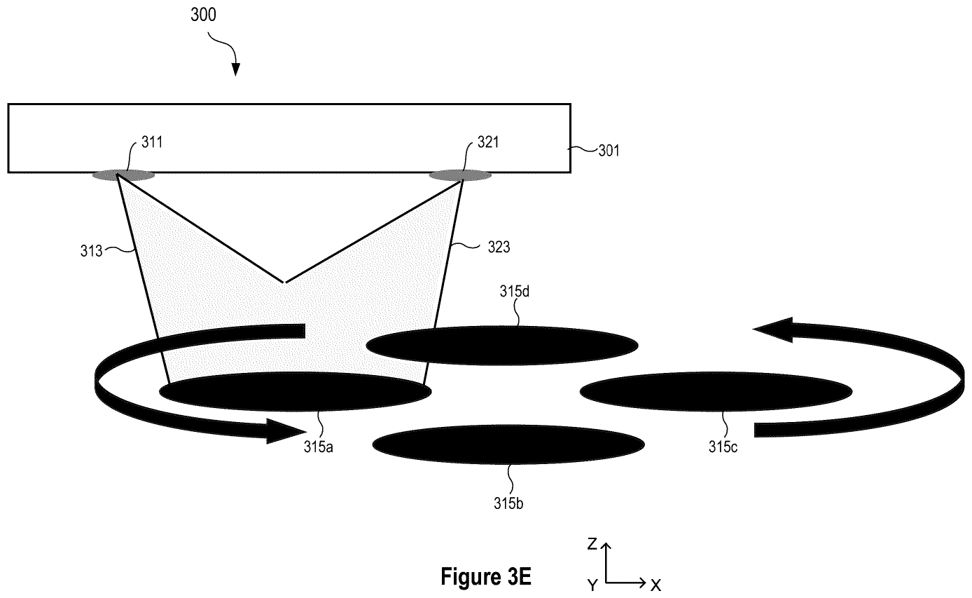

FIG. 1 shows a schematic of an apparatus 100 (also referred to as a system) in accordance with some embodiments of the present disclosure. As illustrated, the apparatus 100 includes an optical bench 101 on which various components are positioned or installed. The apparatus 100 includes a first scanning laser 111 configured to generate and emit a first process beam 112. A first beam splitter 113 can split the first process beam 112 into two portions, including a first portion received by a first monitoring camera 115 and a second portion proceeding to a beam modulator 133 and then a beam steering module 135. The first monitoring camera 115 can thus monitor the first process beam 112 in real time. The second portion of the first process beam 112 can go through a first optical hole 117 of the optical bench 101 towards a first workpiece (not shown here for simplicity purposes; see e.g. 315, 325 and 315a-351d in FIGS. 3A-3E) positioned below the optical bench 101. The first process beam 112 can include a single wavelength, a plurality of discrete wavelengths, a continuous spectrum of wavelengths, or any combinations thereof. Preferably, the first process beam 112 can include one or more wavelengths (e.g. 248 nm, 193 nm, 13.5 nm, etc.) for photoresist exposure in lithography (e.g. ultraviolet lithography, deep ultraviolet lithography, extreme ultraviolet lithography, etc.).

Similarly, the apparatus 100 includes a second scanning laser 121 configured to generate and emit a second process beam 122. A second beam splitter 123 can split the second process beam 122 into two portions, including a first portion received by a second monitoring camera 125 and a second portion proceeding to the beam modulator 133 and then the beam steering module 135. The second monitoring camera 125 can thus monitor the second process beam 122 in real time. The second portion of the second process beam 122 can go through a second optical hole 127 of the optical bench 101 towards a second workpiece (not shown here for simplicity purposes; see e.g. 315, 325 and 315a-351d in FIGS. 3A-3E) positioned below the optical bench 101 or the aforementioned first workpiece. The second process beam 122 can include a single wavelength, a plurality of discrete wavelengths, a continuous spectrum of wavelengths, or any combinations thereof. Preferably, the second process beam 112 can include one or more wavelengths (e.g. 248 nm, 193 nm, 13.5 nm, etc.) for photoresist exposure in lithography (e.g. ultraviolet lithography, deep ultraviolet lithography, extreme ultraviolet lithography, etc.).

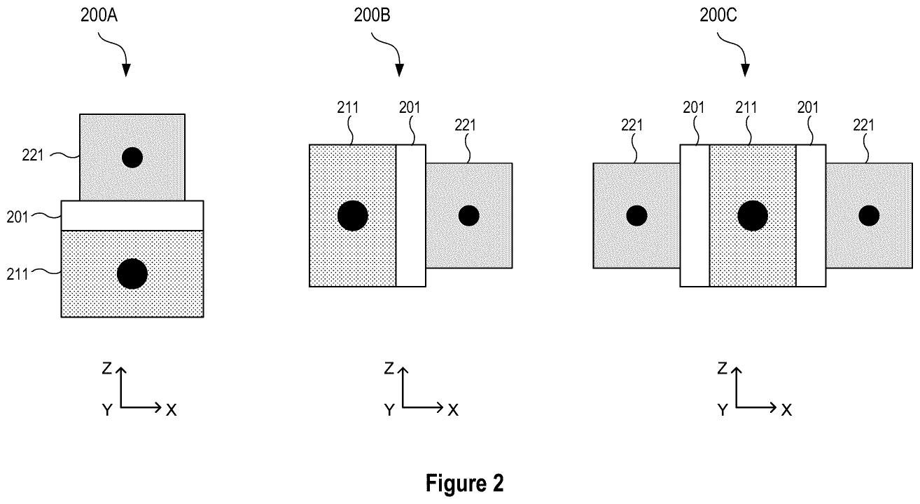

In some embodiments, the optical bench 101 can include a plate 137 having the first optical hole 117 and the second optical hole 127, both of which can be in the form of a through-hole that extends completely through a thickness direction (e.g. the Z direction) of the plate 137. The plate 137 can thus offer optical hole beams. The optical bench 101 can include a bracket (e.g. a mounting bracket, a cooling bracket, etc.) on which various components (e.g. 111, 121, 113, 123, 115, 125, 133, 135, 137, 141, 142, 145 or any combinations thereof) of the apparatus 100 are installed or mounted. For instance, the first scanning laser 111 and the second scanning laser 121 can be mounted on a cooling bracket for temperature control, some embodiments of which will be shown in FIG. 2.

In some embodiments, the first monitoring camera 115 and the second monitoring camera 125 can respectively provide real-time feedback on the functioning of the first scanning laser 111 and the second scanning laser 121. The first beam splitter 113 and the second beam splitter 123 respectively divide the first process beam 112 and the second process beam 122 into multiple parts, working in tandem with the beam modulator 133 to ensure accurate control of the first process beam 112 and the second process beam 122. The beam modulator 133 may include diffraction gratings, polarizers or both. The beam modulator 133 can adjust the first process beam 112 and the second process beam 122, simultaneously or separately, independently or dependently.

The beam steering module 135 may be used for beam scanning (e.g. vector scanning and raster scanning) in different directions (e.g. the X and Y directions). The beam steering module 135 can scan the first process beam 112 across a surface of the aforementioned first workpiece and scan the second process beam 122 across a surface of the aforementioned first or second workpiece, simultaneously or separately, independently or dependently. The beam steering module 135 may include a spinning multi-faceted mirror, a galvanometer scanning mirror, an acousto-optic modulator (AOM) beam deflector, an electro-optic modulator (EOM) beam deflector, a micro-mirror micro-electromechanical system (MEMS) scanning mirror, a piezo-electric scanning mirror or any combinations thereof. Preferably, the beam steering module 135 can include X and Y galvanometers for beam scanning in the X and Y directions.

In some embodiments, the apparatus 100 can include a sensing laser 141 configured to generate and emit a probe beam 142 that is directed by optics e.g. a reflective mirror 143 to be eventually received by a sensing camera 145. The probe beam 142 can be used to detect one or more anomalies of the first process beam 112, the second process beam 122 or both. The apparatus 100 can also include one or more power supplies 131 (or power sources) that provide power for various components of the apparatus 100 e.g. the first scanning laser 111 and the second scanning laser 121. For example, the power suppliers 131 may provide consistent power or programmed varying power to various components of the apparatus 100.

While shown to have two scanning lasers (e.g. 111 and 121), it should be understood that the apparatus 100 may include a plurality of scanning lasers. That is, the number of scanning lasers is not particularly limited and can be for example be any integer of two or more such as two, three, four, five, six, seven, etc. Similarly, while shown to have one beam modulator (e.g. 133a), one beam steering module (e.g. 135) and two beam splitters (e.g. 113 and 123), the apparatus 100 may include any number of beam modulators, any number of beam steering modules and any number of beam splitters. In some examples, the apparatus 100 can include one respective beam modulator, one respective beam steering module and one respective beam splitter for each scanning laser. In some examples, the apparatus 100 can include one common beam modulator, one common beam steering module and one common beam splitter for a plurality of scanning lasers.

In some embodiments, the apparatus 100 can further include a controller 150 having a motherboard 151, a first subunit 161 having a motion control module, a beam steering module, a photodetector or any combinations thereof, and a second subunit 163 having a wire harness bundle, connectors, or any combinations thereof. The motherboard 151, the first subunit 161 and the second subunit 163 can ensure accurate beam direction, system communication and precise positioning.

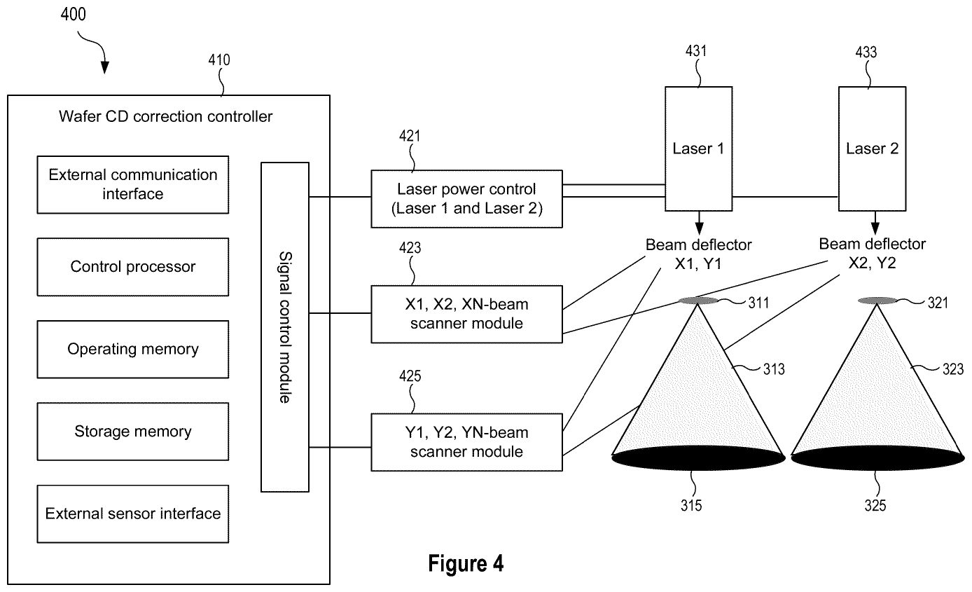

Components of the apparatus 100 can be connected to and controlled by the controller 150 that may optionally be connected to a corresponding memory storage unit and user interface (all not shown herein for simplicity purposes; see e.g. FIG. 4). Various wafer and laser operations can be executed via the user interface, and various wafer and laser processing recipes can be stored in a storage unit. Accordingly, a given wafer can be processed by the apparatus 100 for various purposes.

It will be recognized that the controller 150 may be coupled to various components of the apparatus 100 to receive inputs from and provide outputs for the components. For example, the controller 150 can be configured to receive monitoring data from the first monitoring camera 115 and the second monitoring camera 125 as well as receive sensing data from the sensing camera 145. The controller 150 can also be configured to adjust the first scanning laser 111, the second scanning laser 121, the sensing laser 141, the reflective mirror 143, the first beam splitter 113, the second beam splitter 123, the beam modulator 133, the beam steering module 135 and the power supplies 131. The controller 150 may be configured to adjust knobs and control settings for the apparatus 100. Of course such adjustments can be manually made as well.

The controller 150 can be implemented in a wide variety of manners. In one example, the controller 150 is a computer. In another example, the controller 150 includes one or more programmable integrated circuits that are programmed to provide the functionality described herein. For example, one or more processors (e.g. microprocessor, microcontroller, central processing unit, etc.), programmable logic devices (e.g. complex programmable logic device (CPLD)), field programmable gate array (FPGA), etc.), and/or other programmable integrated circuits can be programmed with software or other programming instructions to implement the functionality of a plasma process recipe. It is further noted that the software or other programming instructions can be stored in one or more non-transitory computer-readable mediums (e.g. memory storage devices, FLASH memory, DRAM memory, reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

FIG. 2 shows vertical and horizontal configurations of an apparatus including two or more scanning lasers such as a first scanning laser 211 and a second scanning laser 221. In a configuration 200A, the first scanning laser 211 and the second scanning laser 221 are stacked in the Z direction with a mounting bracket 201 (or a cooling bracket) in between. Black dots within the first scanning laser 211 and the second scanning laser 221 represent beams generated therein. In a configuration 200B, the first scanning laser 211 and the second scanning laser 221 are placed in parallel to each other. In a configuration 200C, the first scanning laser 211 and two of the second scanning lasers 221 are placed in parallel to each other. Herein, the first scanning laser 211 and the second scanning laser 221 can respectively correspond to (e.g. representing some embodiments of) the first scanning laser 111 and the second scanning laser 121. The mounting bracket 201 may be part of the optical bench 101 or mounted on the optical bench 101.

FIGS. 3A, 3B, 3C, 3D and 3E respectively show schematics of an apparatus 300 in various operating modes in accordance with some embodiments of the present disclosure. The apparatus 300 can correspond to (e.g. representing some embodiments of) the apparatus 100. For simplicity purposes, not all components are shown in FIGS. 3A-3E.

As illustrated in FIG. 3A, the apparatus 100 includes an optical bench 301 with a first optical hole 311 and a second optical hole 321 formed therein. A first process beam 313 going through the first optical hole 311 is directed towards a first wafer 315 positioned on a first wafer holder 316. A second process beam 323 going through the second optical hole 321 is directed towards a second wafer 325 positioned on a second wafer holder 326.

The optical bench 301 can correspond to the optical bench 101. The first optical hole 311 can correspond to the first optical hole 117. The first process beam 313 can correspond to the first process beam 112. The second optical hole 321 can correspond to the second optical hole 127. The second process beam 323 can correspond to the second process beam 122. Similar descriptions have been provided above and will be omitted herein for simplicity purposes. Note that the first optical hole 311 and the second optical hole 321 can each be a through-hole formed in the optical bench 301, although shown to have a shallow penetration depth. The beam steering module 135, the beam modulator 133 and other optics (e.g. 113 and 123) can be positioned on opposing sides of the optical bench 301 relative to wafer holders (e.g. 316 and 326) and are omitted herein for simplicity purposes.

This configuration can be designed to enhance the efficiency of wafer processing, effectively doubling the throughput compared to the standard yield hunter system. The first scanning laser 111 and the second scanning laser 121 can be configured to operate alternately or simultaneously, depending on the specific requirements of the process. In one embodiment, the first process beam 313 and the second process beam 323 are generated simultaneously by the first scanning laser 111 and the second scanning laser 121 respectively. As a result, the first wafer 315 and the second wafer 325 can be processed simultaneously. In another embodiment, the first process beam 313 and the second process beam 323 are generated alternately by the first scanning laser 111 and the second scanning laser 121 respectively. As a result, wafers on the first wafer holder 316 and the second wafer holder 326 may be processed alternately.

As discussed earlier, the apparatus 100 can include a beam steering module 135, which is omitted in FIGS. 3A-3E for simplicity purposes. The beam steering module 135 can scan the first process beam 313 across at least a portion of a surface of the first wafer 315. The first process beam 313 can be deflected within a cone shape to the surface of the first wafer 315 for the purpose of energy deposition for film or surface modification. The cone shape represents the extremes or boundaries of beam travel enabled by the beam steering module 135. Similarly, the beam steering module 135 can scan the second process beam 323 across at least a portion of a surface of the second wafer 325. The second process beam 323 can be deflected within a cone shape to the surface of the second wafer 325 for the purpose of energy deposition for film or surface modification. The cone shape represents the extremes or boundaries of beam travel enabled by the beam steering module 135.

Additionally, the apparatus 300 may include any number of process beams (e.g. 313 and 323) going through any number of optical holes (e.g. 311 and 321) to treat any number of wafers (e.g. 315 and 325) while only two of each component are shown. Additionally, the first process beam 313 and the second process beam 323 can each independently include a single wavelength, a plurality of discrete wavelengths, a continuous spectrum of wavelengths, or any combinations thereof. The first process beam 313 and the second process beam 323 may include the same or different wavelength(s).

In FIG. 3B, the first scanning laser 111 is used to generate the first process beam 313 to treat (e.g. characterize, process or both) the first wafer 315 while the second scanning laser 121 is idle as a backup or spare laser. In other words, the second scanning laser 121 is not in use and does not generate the second process beam 323. However, when a failure occurs with the first process beam 313 or the first scanning laser 111, a user may stop using the first scanning laser 111 and start to use the second scanning laser 121 to generate the second process beam 323 to treat (e.g. characterize, process or both) one or more wafers. Alternatively, FIG. 3B can show an embodiment where the second process beam 323 is located in a different plane and thus not shown.

In FIG. 3C, a first optical sensor 319 can be used to detect a first optical signal 317 reflected and/or emitted from the first wafer 315, and a second optical sensor 329 can be used to detect a second optical signal 327 reflected and/or emitted from the second wafer 325.

In FIG. 3D, the first process beam 313 and the second process beam 323 can be used to treat (e.g. characterize, process or both) the first wafer 315.

In FIG. 3E, the first process beam 313 and the second process beam 323 can be used to treat (e.g. characterize, process or both) wafers 315a, 315b, 315c, 315d, etc. sequentially, e.g. one wafer at a time.

Additionally in FIGS. 3A-3E, when laterally scanning the first process beam 313 on the first wafer 315 and/or laterally scanning the second process beam 323 on the second wafer 325, a scanning boundary can be determined by a retroreflective material for example using techniques disclosed in U.S. Pat. No. 10,145,672B2.

FIG. 4 shows a schematic of an apparatus 400 in accordance with some embodiments of the present disclosure. The apparatus 400 can be used for critical dimension (CD) correction and therefore include a wafer CD correction controller 410. In some embodiments, the apparatus 400 can correspond to the apparatus 100, and the wafer CD correction controller 410 can be part of the controller 150.

In some embodiments, a primary process (e.g. a photoresist exposure process, a film deposition, an etching process, etc.) is performed on a workpiece (e.g. 315 and 325). However, the workpiece after the primary process fails to meet one or more pre-determined requirements. As a result, a secondary adjustment is needed for the primary process. Particularly for a photoresist exposure process, a wafer having a photoresist layer formed thereon is exposed to patterned actinic radiation which alters the solubility of the photoresist layer. The photoresist layer can then be developed to form a pattern with a CD. However, the CD may not meet a pre-determined target value due to various process variations, and a secondary adjustment process can be executed by the apparatus 400 to correct the CD.

The wafer CD correction controller 410 can include an external communication interface (also referred to as a user interface such as an Ethernet connection or any other type of network or connection capable of receiving external information and/or displaying external information), a control processor for generating substrate signature correction maps, an operating memory for providing temporary storage for the control processor, a storage memory (e.g. SRAM, FLASH memory, magnetic or optical disc storage or any other type of memory) for storing wafer CD information (e.g. substrate signature maps, substrate signature correction maps, error corrected signature correction maps, and linearized scan files), an external sensor interface and a signal control module. The signal control module can receive inputs from and provide instructions for a laser power control module 421, a first beam scanner module 423 (also referred to as a first beam position driver) and a second beam scanner module 425 (also referred to as a second beam position driver). The signal control module can provide digital and/or analog output signals to control beam power and positioning.

In a non-limiting example, a secondary adjustment process is needed to correct CD of a (primary) photoresist exposure process. A CD signature map can be generated by a metrology tool to obtain a map of CD distribution across a surface of the first wafer 315. Then a CD correction map can be generated by the control processor of the wafer CD correction controller 410 by comparing the CD signature map and pre-determined CD requirements. Therefore, the CD correction map contains information regarding CD error compensation through a secondary adjustment to the (primary) photoresist exposure process by location-dependent pre-exposure or post-exposure dosing adjustment. For instance, the wafer CD correction controller 410 can control beam power, beam positioning and/or beam scanning trajectories to achieve a secondary adjustment in the form of a location-dependent exposure after the (primary) photoresist exposure process. Particularly, the secondary adjustment can be accomplished by e.g. varying a laser energy of the first process beam 313 on the first wafer 315 to induce location-dependent changes to a photoresist layer formed on the first wafer 315, when laterally scanning the first process beam.

As mentioned earlier, the first process beam 313 may include a single wavelength, a plurality of discrete wavelengths, a continuous spectrum of wavelengths, or any combinations thereof. Preferably, the first process beam 313 in the secondary adjustment and patterned actinic radiation in the (primary) photoresist exposure process can include at least one identical wavelength, at least one identical continuous spectrum of wavelengths or any combinations thereof. Additionally or alternatively, the first process beam 313 and the patterned actinic radiation may include different wavelengths.

In some embodiments, historical data collected on historical wafers in historical photoresist exposure processes can be used to determine a typical or average CD signature map for a specific exposure tool. Accordingly, a secondary adjustment may be executed prior to a primary photoresist exposure process for a new wafer. Note that such secondary adjustment described herein can also be executed by the apparatus 100, the apparatus 300, and the like. Similar secondary adjustment can be executed by the second process beam 323 on the second wafer 323 or the first wafer 313. Descriptions have been provided above and will be omitted for simplicity purposes.

The laser power control module 421 can be used to adjust power settings of a first scanning laser 401, a second scanning laser 402 or both. The first scanning laser 401 and the second scanning laser 402 are respectively directed towards the first wafer 315 and the second wafer 325 via a first beam deflector and a second beam deflector. The first beam deflector can include various optical components such as the first beam splitter 113, the beam modulator 133, the beam steering module 135, etc. The second beam deflector can include various optical components such as the second beam splitter 123, the beam modulator 133, the beam steering module 135, etc. Accordingly, the first beam scanner module 423 can independently adjust each component of the first beam deflector and the second beam deflector in the X direction. The second beam scanner module 425 can independently adjust each component of the first beam deflector and the second beam deflector in the Y direction. For example, the first beam scanner module 423 and the second beam scanner module 425 can independently scan the first process beam 313 across the first wafer 315 and the second process beam 323 across the second wafer 325 or the first wafer 315.

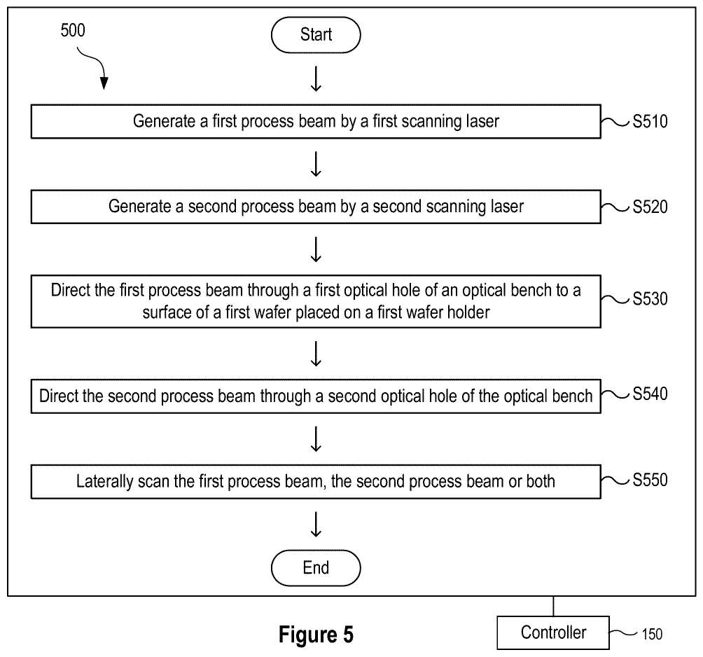

FIG. 5 shows a flow chart of a process 500 for wafer processing, in accordance with some embodiments of the present disclosure. At step S510, a first process beam is generated by a first scanning laser. At step S520, a second process beam is generated by a second scanning laser. At step S530, the first process beam is directed through a first optical hole of an optical bench to a surface of a first wafer placed on a first wafer holder. At step S540, the second process beam is directed through a second optical hole of the optical bench. At step S550, the first process beam, the second process beam or both are laterally scanned.

In some embodiments, the controller 150 may be coupled to various components of the process 500 to receive inputs from and provide outputs for the components. For example, the controller 150 can implement steps S510, S520, S530, S540 and/or S550. Of course, one or more functions of the controller 150 can also be manually accomplished.

As discussed above, techniques herein provide a multiple (e.g. dual) scan laser system (e.g. 100, 200, 300 and 400; hereinafter referred to as the system) designed to increase wafer throughput. The system can include a pair of scanning lasers, a pair of monitoring cameras, at least one sensing laser, multiple beam splitters, power suppliers, and beam modulators. This system is designed to enhance the efficiency of wafer processing, effectively doubling the throughput compared to the standard yield hunter system. The dual scan laser system may operate on the principle of light reflection and refraction. The scanning lasers are configured to operate in various modes, e.g. alternately or simultaneously, depending on the specific requirements of the process. This flexibility in operation allows for a more optimized and efficient wafer processing system.

The system exhibits advantageous properties such as high precision, reliability, and efficiency. The inclusion of beam modulators, which include diffraction gratings, polarizers or both, allows for accurate control of the laser beams. The system can also include a set of galvanometers for each of the X and Y axes, an optical hole beam, beam steering mirrors, a motherboard, a motion control module, a beam steering module, and photodetectors.

The dual scan laser system offers several advantages. It reduces tool downtime by including a spare laser pre-aligned on an optical bench. It also utilizes artificial intelligence learning from one laser and optics system and applying the learning to another laser and optics system. Furthermore, a digital twin can be utilized for operation and continuous enhancement of the dual laser system at a remote location, enhancing the overall efficiency and productivity of the system.

The dual scan laser system can be prepared by assembling the various components in a specific configuration. For example, the pair of scanning lasers, monitoring cameras, sensing laser, beam splitters, power suppliers, and beam modulators can be all integrated into a single system. The optical alignment may be completed at the factory prior to tool installation to reduce installation time.

The system can be operated in different modes depending on the specific requirements. For example, one operating mode may use one scanning laser with the other laser idle as a backup. In another operating mode, two scanning lasers may be used simultaneously. These different configurations provide flexibility in the system's operation, allowing it to cater to different process requirements.

The system can also include an optical module designed to expose multiple substrates simultaneously. This module includes a pair of lasers and a pair of optics. The module is configured to alternate the use of the lasers and optics or operate only one until failure, then switch to the backup laser and optics. This design further enhances the system's efficiency and reliability. The optical module can operate on the principle of light reflection and refraction. The lasers and optics work in tandem to expose the substrates, and the system can switch between the lasers and optics as needed. This flexibility in operation allows for more efficient and reliable substrate exposure.

The optical module exhibits advantageous properties such as high precision and reliability. The lasers and optics can be designed to last for different durations, for example with the laser optics having a lifespan of about 6 months and the system optics having a lifespan of about 2 years. This design ensures that the system can continue to operate even if one component fails. The optical module offers several advantages. It reduces tool downtime by having a spare laser that is pre-aligned built onto the optical bench. It can also utilize artificial intelligence learning from one laser and optics system for another laser and optics system while not in use. Furthermore, a digital twin can be utilized at a remote location for operation and continuous enhancement of the dual laser system.

The optical module can be prepared by assembling the various components in a specific configuration. For example, the pair of lasers and pair of optics can be integrated into a single module. The optical alignment may be completed at the factory prior to tool installation to reduce installation time.

The optical module can be operated in different modes depending on the specific requirements. For example, one operating mode may use one laser and one set of optics with the others used as backups. In another operating mode, both lasers and both sets of optics may be used simultaneously. These different configurations provide flexibility in the module's operation, allowing it to cater to different process requirements.

Techniques herein provide a multiple (e.g. dual) scan laser system. This laser system successfully amplifies the wafer throughput by at least twice the standard yield hunter system's capacity. The system includes multiple components such as at least two scanning lasers, a pair of monitoring cameras, one or more sensing lasers, several beam splitters, and power suppliers. Additionally, it includes beam modulators, which could take the form of diffraction gratings polarizers, or both. The galvanometer count for both the X and Y axes can vary, with at least one galvanometer for each axis. Other components of the system may include an optical hole beam, beam steering mirrors, a motherboard, a motion control module, a beam steering module, and photodetectors. These components can work together to achieve a significant enhancement in wafer processing efficiency, thereby effectively improving the throughput in comparison to the standard yield hunter system.

In some embodiments, the system includes the Yield Hunter dual laser scanning along with the dual optics compact module. This design is aimed to house double optics e.g. laser optics and control system optics. These optics have different life spans, for example with the laser optics having a lifespan of about 6 months while the system optics can last for up to 2 years. This module is equipped with a pair of lasers and optics. The configuration of this module allows for the lasers and optics to be used alternatively, or to operate one until failure, then switch to the backup laser and optics. This configuration provides a robust and reliable system that ensures continuous operation, even in the event of component failure.

In some embodiments, the optical alignment is completed at the factory before the tool installation, which effectively reduces the time required for tool installation. Techniques herein also enable the use of a single optical module to expose more than two substrates simultaneously. This design allows for a more compact design of the Yield Hunter system, as it incorporates two laser and optic systems in a reduced fab tool. The compact design not only saves space but also enhances the efficiency of the system.

In some embodiments, the tool downtime is significantly reduced by having a pre-aligned spare laser built onto the optical bench. Furthermore, the system utilizes artificial intelligence to learn from one laser and optic system and apply the learning to another laser and optic system while not in use. This AI learning capability enhances the performance of the system by allowing it to continuously improve and optimize its performance based on past experiences.

In some embodiments, the system utilizes a digital twin at a remote location for operation and continuous enhancement of the dual laser system. It also enables all yield hunter tools to connect for process optimization at multiple factory locations. The connectivity provided allows for centralized control and optimization of the entire production process, thereby improving efficiency and productivity.

In some embodiments, the dual scan laser system is configured to operate in at least two modes. The first mode uses one scanning laser while the other laser is idle as a backup. In this mode, only one laser beam is visible from the cross section, since the other laser beam is not generated (or is located into the plane of the paper) and is idle as a backup laser. On the other hand, the second mode uses both scanning lasers simultaneously. In this mode, both laser beams are visible from the cross section. The system can accommodate N scanning lasers as options, providing flexibility and scalability in operation.

In some embodiments, the system incorporates the substrate CD signature correction controller. This controller includes various components including an external communication interface, a control processor, an operating memory, a storage memory, and an external sensor interface. The system also includes a signal control module that includes a beam position driver for the dual laser system. This comprehensive control system ensures precise and accurate operation of the dual laser system.

Additionally, the system is also capable of critical dimension (CD) optimization with a single optical scanned cone for one substrate. Alternatively, it can provide simultaneous CD wafer optimization with dual scanned optical cones for two substrates. This flexibility allows the system to adapt to different production requirements and optimize its performance accordingly.

Compared to prior art such as U.S. Pat. Nos. 10,108,096B2, 10,503,083B2, and 10,145,672B2, the present disclosure offers significant advantages. The laser system of the present disclosure can double the wafer throughput, which is a substantial advancement from the prior art. The present disclosure also incorporates artificial intelligence and a digital twin model, which are novel features that enable continuous improvement and enhancement of the laser system's performance. In addition, the design of the present disclosure is more compact and efficient, enabling simultaneous exposure of multiple substrates, reducing tool downtime, and allowing for process optimization at various factory locations.

Techniques herein can offer a unique feature of having a spare laser pre-aligned on the optical bench, which significantly reduces tool downtime. This feature is absent in the prior art technologies and is a salient advantage of the present disclosure. Furthermore, the AI learning feature of the present disclosure is a novel concept that enables the system to adapt and learn from one laser and optic system for another laser and optic system while not in use, enhancing the overall efficiency and productivity of the system.

It is important to note that the embodiments of the present disclosure disclosed herein are intended to be illustrative and not limiting. Other embodiments are possible, and modifications may be made to the embodiments without departing from the spirit and scope of the invention. As such, these embodiments are only illustrative of the inventive concepts contained herein.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically and interchangeably refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of wafer processing, comprising:
generating a first process beam by a first scanning laser;
generating a second process beam by a second scanning laser;
directing the first process beam through a first optical hole of an optical bench to a surface of a first wafer placed on a first wafer holder;
directing the second process beam through a second optical hole of the optical bench; and
laterally scanning the first process beam, the second process beam or both.

2. The method of claim 1, wherein:
the second process beam is directed through the second optical hole to the surface of the first wafer.

3. The method of claim 2, wherein:
the first process beam and the second process beam are generated simultaneously.

4. The method of claim 1, wherein:
the second process beam is directed through the second optical hole to a surface of a second wafer placed on a second wafer holder.

5. The method of claim 4, wherein:
the first process beam and the second process beam are generated simultaneously to process the first wafer and the second wafer simultaneously.

6. The method of claim 4, wherein:
the first process beam and the second process beam are generated alternately for alternate wafer processing.

7. The method of claim 1, further comprising:
generating a critical dimension (CD) correction map based on a CD signature map of the first wafer and pre-determined CD requirements, the CD signature map including CD distribution of the first wafer as a result of a photoresist exposure process; and
executing a location-dependent exposure dosing adjustment based on the CD correction map.

8. The method of claim 7, wherein:
the executing comprises varying a laser energy of the first process beam on the first wafer to induce location-dependent changes to a photoresist layer formed on the first wafer, when laterally scanning the first process beam.

9. The method of claim 8, further comprising:
before the generating the CD correction map, executing the photoresist exposure process to expose the photoresist layer to patterned actinic radiation.

10. The method of claim 9, wherein:
the location-dependent changes are induced to adjust the CD distribution of the first wafer.

11. The method of claim 1, further comprising:
before a failure occurs with the first scanning laser, using the first scanning laser while the second scanning laser is idle; and
after the failure occurs with the first scanning laser, using the second scanning laser.

12. The method of claim 11, further comprising:
pre-aligning the second scanning laser on the optical bench before the using the first scanning laser.

13. The method of claim 1, further comprising:
splitting the first process beam by a first beam splitter; and
splitting the second process beam by a second beam splitter.

14. The method of claim 13, further comprising:
monitoring the first process beam by a first monitoring camera; and
monitoring the second process beam by a second monitoring camera.

15. The method of claim 14, wherein:
the first process beam is split by the first beam splitter so that part of the first process beam is received by the first monitoring camera, and
the second process beam is split by the second beam splitter so that part of the second process beam is received by the second monitoring camera.

16. The method of claim 1, further comprising:
adjusting the first process beam, the second process beam or both, by a beam modulator.

17. The method of claim 16, wherein:
the beam modulator comprises diffraction gratings, polarizers or both.

18. The method of claim 1, further comprising:
detecting an anomaly of the first process beam, the second process beam or both, by a sensing laser and a sensing camera.

19. The method of claim 1, wherein:
the laterally scanning is executed by a beam steering module comprising galvanometers.

20. The method of claim 4, further comprising:
collecting data on the first scanning laser and the first wafer; and
adjusting the second scanning laser and the second wafer based on the data.
